(19) United States
(12) Patent Application Publication
(10) Pub. No.: US 2002/0106881 A1
(43) Pub. Date: Aug. 8, 2002

(54) Prevention of contact failure by hydrogen treatment

(76) Inventor: Manoj K. Jain, Plano, TX (US)

Correspondence Address: TEXAS INSTRUMENTS INCORPORATED, P O BOX 655474, M/S 3999, DALLAS, TX, 75265

(21) Appl. No.: 10/006,578

(22) Filed: Dec. 6, 2001

Related U.S. Application Data
(60) Provisional application No. 60/254,036, filed on Dec. 7, 2000.
(60) Provisional application No. 60/261,058, filed on Jan. 11, 2001.

(51) Int. Cl. H01L 21/44

(52) U.S. Cl. 438/600

(57) ABSTRACT

A contact (160) is formed by depositing a conductive liner (130), treating the liner (130) with hydrogen, depositing a conductive barrier (140), and filling the contact hole (120) with a metal (150). Hydrogen treatment improves contact resistance and adhesion between the liner (130) and barrier (140). The hydrogen treatment may be a hydrogen plasma treatment and may be performed one or more times during contact formation such as after contact etch, after liner deposition, during liner anneal, after liner anneal, or after barrier deposition.

### FIELD OF THE INVENTION

The invention is generally related to the field of forming contacts in semiconductor devices and more specifically to reducing contact failure.

### BACKGROUND OF THE INVENTION

In semiconductor device fabrication, interconnections within the device are accomplished using metal interconnect layers in conjunction with contacts and vias. Contacts typically provide connection between the transistor/semiconductor level and the first metal interconnect layer. Vias typically provide connection between different metal interconnect layers.

One commonly used method to fabricate contacts is to deposit the pre-metal dielectric layer (PMD) and then pattern and etch contact holes within the PMD. After the contact holes are cleaned, a conductive liner such as titanium is deposited over the sidewalls and bottom of the contact hole. After the conductive liner is deposited, it is annealed. For example, a furnace anneal at 500-1000° C. for 10 minutes to 2 hours may be used, or a RTP (rapid thermal process) at 600-1000° C. for 15-180 sec. Next, a thin conductive barrier such as TiN is deposited over the annealed conductive liner. The contact holes are then filled with a conductive metal such as tungsten. The conductive metal, barrier and liner are then etched or polished back until they are roughly planar with the PMD surface thus forming the contact. A metal interconnect layer is then formed over the surface of the contact and PMD.

Some of the issues that can occur with the formation of contacts include poor contact resistance, poor mechanical strength, or adhesion-related failures. After formation of the contact, subsequent processing steps can cause the contact resistance to degrade or even mechanical/adhesion failure due to relatively large variations in temperature and/or the deposition of high stress films. Deposition of a dielectric film (such as nitride, doped oxide, undoped oxide, or organic dielectric) over contacts or at some point during the multilevel interconnect formation can induce failure in the contacts. Deposition of a conductive film such as aluminum, TiN or Ti over the contact can also cause similar failures.

### SUMMARY OF THE INVENTION

The invention is a method for preventing contact failure using a hydrogen treatment. The hydrogen treatment is performed sometime after contact etch and before the metal fill layer is deposited. For example, the hydrogen treatment may be performed after a conductive liner is deposited and annealed.

An advantage of the invention is the prevention of contact failure.

This and other advantages will be apparent to those of ordinary skill in the art having reference to the specification in conjunction with the drawings.

### BRIEF DESCRIPTION OF THE DRAWINGS

In the drawings:

FIGS. 1A-1D are cross-sectional diagrams of the method of forming a contact according to an embodiment of the invention, at various stages in the fabrication process.

### DETAILED DESCRIPTION OF THE EMBODIMENTS

The invention will now be described in conjunction with a method for forming tungsten contacts in a semiconductor device. It will be apparent to those of ordinary skill in the art that the benefits of the inventions may be applied to other portions of a semiconductor process, such as the formation of vias, as well as to metals other than tungsten such as aluminum and copper.

One of the reasons contacts fail is believed to be related to a poor interface between the conductive liner and the conductive barrier deposited over it. For example, there may be a contaminated interface or an oxidized interface. A poor interface leads to poor contact resistance, mechanical failure, or adhesion related failure.

The invention utilizes a hydrogen treatment to prevent contact failure. Hydrogen treatment of the liner can help in reducing some of the contact defects. Hydrogen can be used to “reduce” any native oxide or surface contaminant that forms on the liner via a reduction reaction or removal of oxygen or other contaminant by chemical reaction. Alternatively, the hydrogen may drive the oxygen or other contaminant away from the liner surface. Removal of titanium-oxide is expected to result in a cleaner surface and hence cleaner interface. A cleaner interface is expected to improve contact resistance and also improve the adhesion between the liner and the barrier.

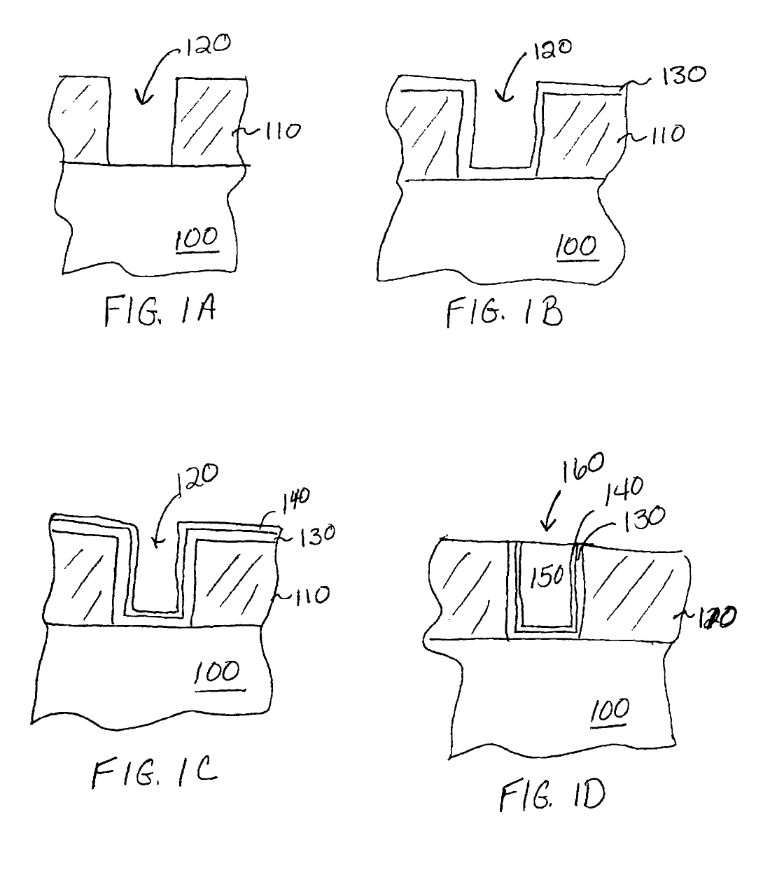

A preferred embodiment of the invention will now be discussed with reference to FIGS. 1A-1D. Referring to FIG. 1A, a semiconductor body 100 is process through the formation of dielectric layer 110. Any desired transistors and isolation structures (not shown) will have previously been formed in semiconductor body 100. For the formation of a contact, dielectric layer 110 is typically referred to as a PMD (pre-metal dielectric) layer. Dielectric layer 110 is typically an oxide such as BPSG (Boron and Phosphorous doped Silicate Glass). Other suitable materials, such as PSG or TEOS (tetraethyloxysilane), will be apparent to those of ordinary skill in the art.

Dielectric layer 110 is patterned and etched to form contact holes 120. Contact holes 120 are formed at locations where contact to semiconductor body 100 is desired. For example, contact to transistor source/drain regions or transistor gates of semiconductor body 100 is typically desired. After pattern and etch, contact holes 120 are typically cleaned to remove any contaminants/etch residue left over from the etch.

Referring to FIG. 1B, a conductive liner 130 is deposited conformally over dielectric layer 110 including within contact hole 120. Conductive liner 130 preferably comprises titanium. Other suitable liner materials, such as a titanium alloy, titanium compound, tantalum, tantalum alloy, or tantalum compound, will be apparent to those of ordinary skill in the art. Conductive liner 130 is a relatively thin layer.

After deposition, the conductive liner 130 is annealed at an elevated temperature. For example, a furnace anneal at 500-100° C. for 10 min. to 2 hours or an RTP anneal at 600-1000° C. for 15-180 sec. may be used.

At this point, the hydrogen treatment according to the invention may be performed. It may be combined with the liner anneal or performed separately. For example, a hydrogen plasma treatment can be performed at a temperature in the range of 50° C. -900° C. for a duration in the range of 15 sec to 10 minutes. The hydrogen may be a pure hydrogen atmosphere or hydrogen mixed with a carrier gas such as nitrogen or argon. Alternatively, a suitable hydrogen containing gas such as ammonia can be used as a source of hydrogen. This can significantly improve the interface between the liner and barrier and prevent adhesion failure and/or lower contact resistance. One of the benefits of hydrogen plasma treatment is that the hydrogen in the plasma can “reduce” the thin oxide layer or surface contaminant, which may have formed on the liner (e.g., titanium) surface. It may drive away any unwanted adsorbed oxygen (or some other contaminant) from the liner surface. In the case of a titanium liner, removal of the titanium oxide is expected to lead to a cleaner surface and hence a cleaner interface. A cleaner interface is expected to improve contact resistance and also improve the adhesion of the liner (e.g. titanium) to barrier (e.g., TiN).

Referring to FIG. 1C, a conductive barrier 140 is deposited over conductive liner 130. Conductive barrier 140 is a relatively thin layer and is typically deposited using a PVD (physical vapor deposition) or CVD (chemical vapor deposition) process. Suitable materials for conductive barrier 140 are known in the art. For example, TiN, TaN, TiSiN, TaSiN, WN, WSIN, a Ti compound, or a TiN compound may be used.

After depositing the conductive barrier 140, contact holes 120 are filled with a conductive metal 150. Conductive metal 150 may, for example, comprise tungsten, aluminum, or copper.

After deposition, the conductive metal 150, conductive barrier 140 and conductive liner 130 are polished or etched back until planar with the dielectric 110 surface, as shown in FIG. 1D. This forms contact 160.

Next, a metal interconnect is formed over the contact 160. Processing then continues to form subsequent metal interconnect levels and packaging of the device.

In alternative embodiments of the invention, the hydrogen treatment is performed at different steps of the process or in different tools. In the above embodiment, the hydrogen treatment is performed after anneal of the liner but prior to deposition of the barrier. Preferably, the hydrogen treatment and barrier deposition are performed in a cluster tool without breaking the vacuum (i.e., without exposing the liner to air). Alternatively, the hydrogen treatment can be done in a cluster tool along with the anneal or all three operations: anneal, hydrogen treatment and barrier deposition, may be performed in the same cluster tool. The hydrogen treatment may also be performed in a standalone tool.

Hydrogen plasma treatment may be performed are one or more steps during the contact formation. For example, it may be used after contact etch but before liner deposition, after liner deposition but before liner anneal, after liner anneal but before barrier deposition, and/or after barrier deposition. However, if the hydrogen treatment is performed in a stand-alone tool, it needs to be does after annealing the liner and before depositing the barrier.

In another embodiment of the invention, the annealing and hydrogen treatment steps are combined. The annealing of the liner could be accomplished in a plasma or non-plasma atmosphere that contains hydrogen. It may partially contain hydrogen or consist completely of hydrogen. The method of annealing can be either conventional furnace annealing or RTP. The annealing in hydrogen atmosphere can be done at a suitable process step, preferably after liner deposition. It can be performed at one or more steps during the contact formation process such as after contact etch, after liner deposition, after annealing the liner, and after barrier deposition.

It should be noted that while the term contact is used throughout the specification, the invention is also applicable to forming vias.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

In the claims:

1. A method of forming a conductive structure in an integrated circuit, comprising the steps of:
forming a dielectric layer over a semiconductor body;
forming a hole in said dielectric layer;
forming a conductive liner in said hole;
annealing said conductive liner;
treating said conductive liner with hydrogen;
forming a conductive barrier over said conductive liner; and
filling said hole with a conductive metal.

2. The method of claim 1, wherein said treating step occurs after said step of forming a hole and before said filling step.

3. The method of claim 1, wherein said annealing step and said treating step are performed simultaneously.

4. The method of claim 1, wherein said treating step comprises a plasma treatment in a hydrogen containing atmosphere.

5. The method of claim 4, wherein said hydrogen containing atmosphere comprises pure hydrogen.

6. The method of claim 4, wherein said hydrogen containing atmosphere comprises hydrogen mixed with a carrier gas.

7. The method of claim 4, wherein said hydrogen containing atmosphere comprises ammonia.

8. The method of claim 1, further comprising the step of repeating said treating step prior to said filling step.

9. A method for forming a contact in an integrated circuit, comprising the steps of:
forming a dielectric layer over a semiconductor body;
etching a contact hole extending through said dielectric layer;
depositing titanium over said dielectric layer, including on exposed surfaces within said contact hole;
annealing said titanium;
treating said titanium with hydrogen;
depositing TiN over said titanium; and
filling said contact hole with tungsten.

10. The method of claim 9, wherein said annealing step and said treating step are performed simultaneously.

11. The method of claim 9, wherein said treating step is performed after said etching step and before said filling step.

12. The method of claim 9, wherein said treating step comprises a plasma treatment in a hydrogen containing atmosphere.

13. The method of claim 12, wherein said hydrogen containing atmosphere comprises pure hydrogen.

14. The method of claim 12, wherein said hydrogen containing atmosphere comprises hydrogen mixed with a carrier gas.

15. The method of claim 12, wherein said hydrogen containing atmosphere comprises ammonia.

16. The method of claim 9, further comprising the step of repeating said treating step prior to said filling step.
